(19) United States
(12) Patent Application Publication
(10) Pub. No.: US 2026/0098896 A1
(43) Pub. Date: Apr. 9, 2026

(54) RECALIBRATION OF COMPACT MODELS OF SEMICONDUCTOR DEVICES

(71) Applicant: INTERNATIONAL BUSINESS MACHINES CORPORATION, ARMONK, NY (US)

(72) Inventors: LAN LUO, South Burlington, VT (US); Richard Andre Wachnik, Mount Kisco, NY (US); David Wells Winston, Asheville, NC (US); Robert Perricone, New City, NY (US); Bria Matthews, Austin, TX (US)

(21) Appl. No.: 18/906,099

(22) Filed: Oct. 3, 2024

(51) Int. Cl. G01R 31/28; G01R 31/3183

(52) U.S. Cl. CPC G01R 31/2848; G01R 31/318314

(57) ABSTRACT

A plurality of benchmarking circuits that mimic different types of circuits in a product chip are tested to produce measurements of targets of a semiconductor device in the benchmarking circuits, and measurements of targets of the benchmarking circuits. Computer simulations of the plurality of benchmarking circuits are performed with local layout effect (LLE) evaluation to predict values of the targets of the semiconductor device and the targets of the benchmarking circuit. The measurements and predicted values of the targets are used to perform recalibration of a compact model of the semiconductor device.

### BACKGROUND

### Technical Field

The present disclosure generally relates to electronic design of semiconductor devices, and more particularly, to recalibration of compact models of transistors and other semiconductor devices.

### Description of the Related Art

A model of a semiconductor device includes equations that describe how characteristics of the semiconductor device change under various conditions. Physics-driven device models are accurate but not fast enough for simulation. Compact models, in contrast, are empirical models derived from simplified physics in order to achieve faster simulation times. They model electrical characteristics of semiconductor devices.

Compact models are broadly used in circuit simulators, such as SPICE (Simulation Program with Integrated Circuit Emphasis) simulators. A netlist including the device's instance parameter values and stimulus are supplied to a simulator. The simulator uses the compact model and the netlist to predict the behavior of the device or integrated circuit. The ability to model and simulate device behavior under different operating conditions (e.g., different voltage and current levels, temperature, and process variations) allows design engineers to reduce the dependency on costly physical prototypes, saving both time and resources.

Prior to simulation, compact models are calibrated based on electrical measurement data. For example, a metal oxide semiconductor field effect transistor (MOSFET) model is calibrated to comprehensive current-voltage (I-V) and capacitance-voltage (C-V) measurement across operating ranges from a variety of test structures. This process is referred to as “asfit calibration.”

Due to semiconductor manufacturing complexity, it usually takes a couple of years to develop a mature-node technology. During the development period, device compact models are recalibrated periodically in order to enhance prediction capability. Instead of using hundreds of model parameters to fit massive measurement data during asfit calibration, model recalibration is usually performed with only a subset of model parameters to match a limited set of targets.

Most asfit calibration and recalibration methods use silicon measurements of direct current (DC) or low frequency targets. Examples of targets for MOSFET model calibration include threshold voltage (Vth), effective current (Ieff), and on-condition gate capacitance (Cgon).

### SUMMARY

According to an embodiment of the present disclosure, a method includes testing a plurality of benchmarking circuits that mimic different types of circuits in a product chip to produce measurements of targets of a semiconductor device in the benchmarking circuits and measurements of targets of the benchmarking circuits. The method further includes performing computer simulations of the plurality of benchmarking circuits with local layout effect (LLE) evaluation to predict values of the targets of the semiconductor device and the targets of the benchmarking circuits; and using the measurements and predicted values of the targets to perform recalibration of a compact model of the semiconductor device.

In some embodiments, the benchmarking circuits mimic the product chip in at least one of figures of metrics (FOM), layouts, and different topologies in the product chip.

In some embodiments, each benchmarking circuit includes a multi-stage ring oscillator for representing main logic gates. Targets of the benchmarking circuits includes power and leakage.

In some embodiments, the compact model is a compact model of a MOSFET.

In some embodiments, the method further includes extracting parasitic extraction (PEX) netlists for the semiconductor device and extracting PEX netlists for the benchmarking circuits. The PEX netlists are used in the simulations.

In some embodiments, the netlists include parameters for capacitors, resistors and local layout effect.

In some embodiments, using the measurements and predicted values of the targets to perform the recalibration includes selecting a subset of parameters for the recalibration, and iteratively adjusting the subset of parameters to minimize a cost function. The cost function is based on a difference between the measurements and predicted values of the targets.

In some embodiments, the subset of parameters are iteratively adjusted via Bayesian optimization.

In some embodiments, performing the computer simulations and using the measurements and the predicted values to recalibrate the compact model are computer-implemented.

In some embodiments, the method further includes fabricating the plurality of benchmarking circuits.

According to an embodiment of the present disclosure, a computer-implemented method includes accessing measurements taken from a plurality of benchmarking circuits. The measurements include measurements of targets of semiconductor devices in the benchmarking circuits and measurements of targets of the benchmarking circuits. The computer-implemented method further includes accessing a semiconductor device compact model; performing simulations of the plurality of benchmarking circuits with LLE evaluation to predict values of the targets of the semiconductor devices and the targets of the benchmarking circuits; and adjusting a subset of parameters of the compact model to reduce error between the measurements and predicted values of the targets.

In some embodiments, the method further includes iteratively performing the simulations with adjusted parameters of the compact model and then adjusting the parameters again until a cost function is satisfied.

In some embodiments, the adjusted parameters are computed via Bayesian optimization.

In some embodiments, the compact model is a compact model of a MOSFET.

In some embodiments, the method further includes extracting PEX netlists for the semiconductor devices and extracting PEX netlists for the benchmarking circuits. The PEX netlists are used in the simulations.

In some embodiments, the netlists include parameters for capacitors, resistors and local layout effect.

According to an embodiment of the present disclosure, a computer includes memory having computer readable instructions; and a processor set for executing the computer readable instructions to configure the computer to perform a method. The method includes receiving measurements of targets of a plurality of benchmarking circuits including semiconductor devices; receiving measurements of targets of the semiconductor devices; performing simulations of the plurality of benchmarking circuits with LLE evaluation to predict values of the targets of the semiconductor devices and the targets of the benchmarking circuits; and using the measurements and predicted values of the targets to perform recalibration of a semiconductor device compact model.

In some embodiments, the method further includes extracting PEX netlists for the semiconductor devices and PEX netlists for the benchmarking circuits. The PEX netlists are used in the simulations.

In some embodiments, the PEX netlists include parameters for capacitors, resistors and local layout effect.

In some embodiments, using the measurements and the predicted values includes performing Bayesian optimization to find a subset of parameters that minimize a cost function.

According to an embodiment of the present disclosure, a computer program product includes one or more computer-readable memory devices encoded with data including instructions that, when executed, causes a processor set to perform a method. The method includes receiving measurements of targets of a plurality of benchmarking circuits including a semiconductor device; receiving measurements of targets of the semiconductor device; performing simulations of the plurality of benchmarking circuits with LLE evaluation to predict values of the targets of the semiconductor device and the targets of the benchmarking circuits; and using the measurements and predicted values of the targets to perform recalibration of a compact model of the semiconductor device.

In some embodiments, the method further includes extracting PEX netlists for the semiconductor device and the benchmarking circuits, and using the PEX netlists in the simulations.

In some embodiments, the PEX netlists include parameters for capacitors, resistors and local layout effect.

In some embodiments, using the measurements and the predicted values includes performing Bayesian optimization to find a subset of parameters that minimize a cost function.

According to an embodiment of the present disclosure, a method for recalibration of parameters of a MOSFET compact model includes evaluating a MOSFET design and a circuit design for benchmarking; and testing the circuit design. The testing produces measurements of targets of MOSFETs in the circuit design, and measurements of targets of the circuit design. The method further includes identifying key performance metrics (“KPM”) of the circuit design and the MOSFET design; and determining whether the compact model and the circuit design match the KPMs of the MOSFETs and the circuit design. If there is no match, recalibration KPM targets are defined for the MOSFET design and recalibration KPM targets for the circuit design are defined. A first complex PEX netlist including LLE parameters for the MOSFET design is extracted. A second PEX netlist including LLE parameters for the circuit design is also extracted. A subset of model parameters for recalibration is selected, and optimization of the subset of parameters is performed. The optimization includes simulating the circuit design with the PEX netlists and the compact model to predict KPM target values; and adjusting the subset of parameters to minimize a cost function based on the measurements and the KPM target values.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is an illustration of an electronic design automation tool and inputs to the tool, consistent with an illustrative embodiment.

FIG. 2 is a recalibration method, consistent with an illustrative embodiment.

FIG. 3 is an optimization method, consistent with an illustrative embodiment.

FIG. 4 illustrates a first stage of a recalibration method, consistent with an illustrative embodiment.

FIG. 5 illustrates a second stage of the recalibration method, consistent with an illustrative embodiment.

FIG. 6 is a computing environment, consistent with an illustrative embodiment.

### DETAILED DESCRIPTION

### Overview and Support

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

The present disclosure generally relates to recalibration of a semiconductor device compact model used in a simulation of a circuit design of a product chip. By virtue of the concepts discussed herein, accuracy of the compact model is increased, which results in greater simulation accuracy.

According to an embodiment of the present disclosure, a method includes testing a plurality of benchmarking circuits that mimic different types of circuits in a product chip to produce measurements of targets of a semiconductor device in the benchmarking circuits and measurements of targets of the benchmarking circuits. The method further includes performing computer simulations of the plurality of benchmarking circuits with local layout effect (LLE) evaluation to predict values of the targets of the semiconductor device and the targets of the benchmarking circuits; and using the measurements and predicted values of the targets to perform recalibration of a compact model of the semiconductor device.

The combination of the variety of benchmarking circuits and the LLE evaluation greatly increases the accuracy of the recalibration. This, in turn, improves the ability to predict device behavior under different operating conditions (e.g., different voltage and current levels, temperature, and process variations), which, in turn, allows design engineers to further reduce the dependency on costly physical prototypes, saving additional time and resources.

In some embodiments, which can be combined with the previous embodiment, the benchmarking circuits mimic the product chip in at least one of figures of metrics (FOM), layouts, and different topologies in the product chip.

In some embodiments, which can be combined with one or more of the previous embodiments, each benchmarking circuit includes a multi-stage ring oscillator for representing main logic gates. Targets of the benchmarking circuits includes power and leakage.

In some embodiments, which can be combined with one or more of the previous embodiments, the compact model is a compact model of a MOSFET.

In some embodiments, which can be combined with one or more of the previous embodiments, the method further includes extracting parasitic extraction (PEX) netlists for the semiconductor device and extracting PEX netlists for the benchmarking circuits. The PEX netlists are used in the simulations.

In some embodiments, which can be combined with one or more of the previous embodiments, the netlists include parameters for capacitors, resistors and local layout effect. The PEX netlists with LLE parameters increase the accuracy of the simulations.

In some embodiments, which can be combined with one or more of the previous embodiments, using the measurements and predicted values of the targets to perform the recalibration includes selecting a subset of parameters for the recalibration, and iteratively adjusting the subset of parameters to minimize a cost function. The cost function is based on a difference between the measurements and predicted values of the targets.

In some embodiments, which can be combined with one or more of the previous embodiments, the subset of parameters are iteratively adjusted via Bayesian optimization. Bayesian optimization is a computationally efficient approach for finding model parameters that minimize the cost function.

In some embodiments, which can be combined with one or more of the previous embodiments, performing the computer simulations and using the measurements and the predicted values to recalibrate the compact model are computer-implemented.

In some embodiments, which can be combined with one or more of the previous embodiments, the method further includes fabricating the plurality of benchmarking circuits.

According to an embodiment of the present disclosure, a computer-implemented method includes accessing measurements taken from a plurality of benchmarking circuits. The measurements include measurements of targets of semiconductor devices in the benchmarking circuits and measurements of targets of the benchmarking circuits. The computer-implemented method further includes accessing a semiconductor device compact model; performing simulations of the plurality of benchmarking circuits with LLE evaluation to predict values of the targets of the semiconductor devices and the targets of the benchmarking circuits; and adjusting a subset of parameters of the compact model to reduce error between the measurements and predicted values of the targets.

The combination of the variety of benchmarking circuits and the LLE evaluation greatly increases the accuracy of the recalibration. As a result, the ability to predict device behavior under different operating conditions is improved, which enables design engineers to further reduce the dependency on costly physical prototypes, saving additional time and resources.

In some embodiments, which can be combined with the previous embodiment, the method further includes iteratively performing the simulations with adjusted parameters of the compact model and then adjusting the parameters again until a cost function is satisfied.

In some embodiments, which can be combined with one or more of the previous embodiments, the adjusted parameters are computed via Bayesian optimization. Bayesian optimization is a computationally efficient approach for finding model parameters that minimize the cost function.

In some embodiments, which can be combined with one or more of the previous embodiments, the compact model is a compact model of a MOSFET.

In some embodiments, which can be combined with one or more of the previous embodiments, the method further includes extracting PEX netlists for the semiconductor devices and extracting PEX netlists for the benchmarking circuits. The PEX netlists are used in the simulations.

In some embodiments, which can be combined with one or more of the previous embodiments, the netlists include parameters for capacitors, resistors and local layout effect. The PEX netlists with LLE parameters increase the accuracy of the simulations.

According to an embodiment of the present disclosure, a computer includes memory having computer readable instructions; and a processor set for executing the computer readable instructions to configure the computer to perform a method. The method includes receiving measurements of targets of a plurality of benchmarking circuits including semiconductor devices; receiving measurements of targets of the semiconductor device; performing simulations of the plurality of benchmarking circuits with LLE evaluation to predict values of the targets of the semiconductor devices and the targets of the benchmarking circuits; and using the measurements and predicted values of the targets to perform recalibration of a semiconductor device compact model.

The combination of the variety of benchmarking circuits and the LLE evaluation greatly increases the accuracy of the recalibration. As a result, the ability to predict device behavior under different operating conditions is improved, which enables design engineers to further reduce the dependency on costly physical prototypes, saving additional time and resources.

In some embodiments, which can be combined with the previous embodiment, the method further includes extracting PEX netlists for the semiconductor devices and PEX netlists for the benchmarking circuits. The PEX netlists are used in the simulations.

In some embodiments, which can be combined with one or more of the previous embodiments, the PEX netlists include parameters for capacitors, resistors and local layout effect. The PEX netlists with LLE parameters increase the accuracy of the simulations.

In some embodiments, which can be combined with one or more of the previous embodiments, using the measurements and the predicted values includes performing Bayesian optimization to find a subset of parameters that minimize a cost function. Bayesian optimization is a computationally efficient approach for finding model parameters that minimize the cost function.

According to an embodiment of the present disclosure, a computer program product includes one or more computer-readable memory devices encoded with data including instructions that, when executed, causes a processor set to perform a method. The method includes receiving measurements of targets of a plurality of benchmarking circuits including a semiconductor device; receiving measurements of targets of the semiconductor device; performing simulations of the plurality of benchmarking circuits with LLE evaluation to predict values of the targets of the semiconductor device and the targets of the benchmarking circuits; and using the measurements and predicted values of the targets to perform recalibration of a compact model of the semiconductor device.

The combination of the variety of benchmarking circuits and the LLE evaluation greatly increases the accuracy of the recalibration. As a result, the ability to predict device behavior under different operating conditions is improved, which enables design engineers to further reduce the dependency on costly physical prototypes, saving additional time and resources.

In some embodiments, which can be combined with the previous embodiment, the method further includes extracting PEX netlists for the semiconductor device and the benchmarking circuits, and using the PEX netlists in the simulations.

In some embodiments, which can be combined with one or more of the previous embodiments, the PEX netlists include parameters for capacitors, resistors and local layout effect. The PEX netlists with LLE parameters increase the accuracy of the simulations.

In some embodiments, which can be combined with one or more of the previous embodiments, using the measurements and the predicted values includes performing Bayesian optimization to find a subset of parameters that minimize a cost function. Bayesian optimization is a computationally efficient approach for finding model parameters that minimize the cost function.

According to an embodiment of the present disclosure, a method for recalibration of parameters of a MOSFET compact model includes evaluating a MOSFET design and a circuit design for benchmarking; and testing the circuit design. The testing produces measurements of targets of MOSFETs in the circuit design, and measurements of targets of the circuit design. The method further includes identifying key performance metrics (“KPM”) of the circuit design and MOSFETs in the circuit design; and determining whether the compact model and the circuit design match the KPMs of the MOSFETs and the circuit design. If there is no match, recalibration KPM targets are defined for the MOSFET design and recalibration KPM targets are defined for the circuit design. A first complex PEX netlist including LLE parameters for the MOSFET design is extracted. A second PEX netlist including LLE parameters for the circuit design is also extracted. A subset of model parameters for recalibration is selected, and optimization of the subset of parameters is performed. The optimization includes simulating the circuit design with the PEX netlists and the compact model to predict KPM target values; and adjusting the subset of parameters to minimize a cost function based on the measurements and the KPM target values.

The combination of the variety of benchmarking circuits and the LLE evaluation greatly increases the accuracy of the recalibration. As a result, the ability to predict device behavior under different operating conditions is improved, which enables design engineers to further reduce the dependency on costly physical prototypes, saving additional time and resources.

### Example Electronic Design Automation Tool and Method

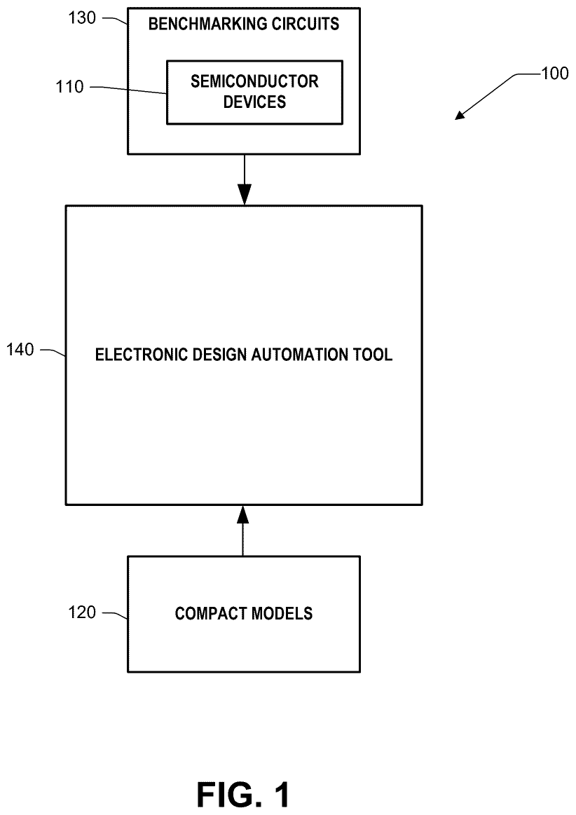

Reference is made to FIG. 1, which illustrates an electronic design automation (EDA) system 100 for recalibrating a compact model of a semiconductor device that is used in a product chip. The product chip refers to a chip that will be manufactured by a foundry. Examples of product chips include memory chips, microprocessors, standard chips, and systems-on-a-chip (SoCs). Examples of circuits in the product chips include digital circuits, analog circuits, and mixed circuits.

These circuits are made up of semiconductor devices 110. Examples of the semiconductor devices 110 include transistors (e.g., MOSFET, Bipolar) and passive devices (resistors, capacitors, and inductors).

Each type of semiconductor device 110 may be described by a compact model 120. An ideal compact model accurately represents a device across a broad set of simulation conditions. One or more compact models 120 are typically supplied in a process development kit (PDK) provided by the foundry.

A plurality of benchmarking circuits 130 mimic different types of circuits in the product chip. The benchmarking circuits are manufactured by the foundry. The following are examples of benchmarking circuits 130.

The product chip design may utilize multiple-Vth MOSFETs with different threshold voltage. The plurality of benchmarking circuits 130 may include multiple-Vth circuits.

The manufacturing of the product chip typically involves many process steps, and with every step there can be imperfections, variability and alignment issues. The foundry may build corner models to predict process extremes, including global variations and local variations. The plurality of benchmarking circuits130 may include multiple process corner models.

The product chip design may include combinational logic circuits and sequential circuits. The plurality of benchmarking circuits 130 may include multiple combinational and sequential circuits.

Logic gates (e.g., AND, OR, XOR, NOT, NAND, NOR and XNOR) form the building blocks for many of the circuits on the product chip. The plurality of benchmarking circuits 130 may include different types of logic gates with different numbers of input gates.

Some benchmarking circuits 130 may mimic the product chip in at least one of figures of metrics (FOM), layouts, and different topologies in the product chip. In general, benchmarking circuit figure-of-metrics (FOMs) should be aligned with product level FOMs. As examples, benchmarking circuit delay is measured to mimic product speed, and benchmarking circuit leakage is measured to mimic product power.

Some benchmarking circuit layouts may capture the product chip's layouts, sizing, and stress environments. Some benchmarking circuits 130 may mimic different circuit topologies in the product chip.

Some benchmarking circuits 130 may include multi-stage ring oscillators for representing main logic gates. Those ring oscillators may be made of different types of logic gates (e.g., AND, OR, XOR, NOT, NAND, NOR and XNOR) with different numbers of input gates.

Static Random Access Memory (SRAM) may be used to represent array structures. Current mirrors may be used to mimic analog modules.

Testing of the benchmarking circuits 130 is performed. The testing includes taking measurements of targets of one or more semiconductor devices 110 used in the benchmarking circuits 130. For example, MOSFET performance targets voltage threshold (Vth), effective current (Ieff), and on-condition gate capacitance (Cgon) may be taken from electrical measurements (I-V and C-V).

The testing further includes taking measurements of targets of the benchmarking circuits 130. Benchmarking circuit targets (e.g., ring oscillator delay, power, and leakage) are characterized from transient measurement, high frequency small signal measurement, and noise measurement.

Target type is determined by the types of benchmarking circuit 130. For example, if only ring oscillators are used in a benchmarking circuit 130, delay, power and leakage may be the targets. If SRAM arrays are used in a benchmarking circuit 130, read current and off state leakage may be targets.

The measurements of the benchmarking circuits 130 and the semiconductor devices 110 are received by an EDA tool 140. The initial compact model 120 is also received by the EDA tool 140. The EDA tool 140 performs recalibration of the compact model 120.

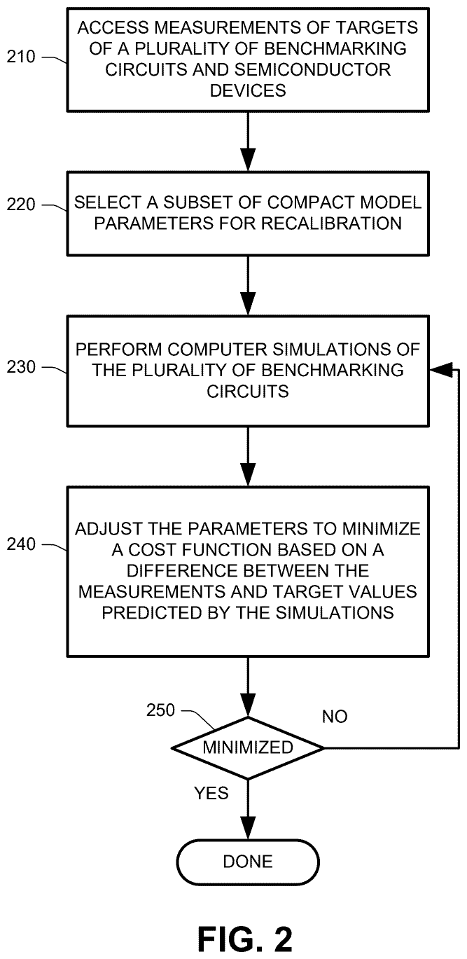

Additional reference is made to FIG. 2, which illustrates functions performed by the EDA tool 140. At block 210, measurements of semiconductor devices and benchmarking circuits are accessed, and recalibration targets are extracted from the measurements.

At block 220, a subset of parameters is selected for the recalibration. The subset is selected from the limited set of targets from block 210.

At block 230, a computer simulation of each of the device and the plurality of benchmarking circuits is performed. The computer simulations predict values of the targets of the semiconductor device and the targets of the benchmarking circuits. The simulations may be performed by a SPICE simulator.

The simulations are performed with local layout effect (LLE) evaluation. LLE refers to the impact that the physical layout of transistors and other components in a circuit has on their electrical characteristics, particularly in advanced semiconductor processes. These effects arise due to interactions between adjacent devices, variations in the manufacturing process, and the proximity of components, and can significantly influence the performance, reliability, and behavior of circuits. LLE can affect timing, power consumption, and speed.

LLE parameters can characterize the effect of neighboring devices (e.g., the effect on a transistor due to stress, strain, or doping concentrations in the silicon, which can be altered by the layout and density of the neighboring transistors). LLE parameters can characterize the effect of differences in diffusion lengths, spacing, orientation, and density. They can characterize the effect of trenches used to isolate transistors and induce mechanical stress in silicon.

The SPICE simulator uses netlists to perform simulations. A SPICE netlist is a text-based representation of a circuit. The representation may include circuit topology and circuit models.

Full parasitic extraction netlists may be extracted from the layouts or a TCAD device profile (TCAD is an acronym for technology computer aided design). The PEX extraction can be either field solver based or rule based. Usually, field solver based PEX extraction is applied to TCAD, and rule based PEX extraction is applied to layouts.

The PEX netlists are preferably as physically accurate as possible. Such physically accurate netlists might be described as “fully extracted” or fully coupled. The physically accurate extraction might also use 3D solvers to capture complex geometries or perhaps inductive effects. PEX netlists associated with the semiconductor devices may be extracted with parasitic capacitors, resistors and LLE parameters. PEX netlists associated with the benchmarking circuits may be extracted with parasitic capacitors, resistors and LLE parameters.

At block 240, the subset of parameters is adjusted towards minimization of a cost function. The cost function may be based on a difference between the measurements and predicted values of the targets. Control is returned to block 230 and simulations with the adjusted parameters are performed. The adjustment is performed iteratively until the cost function is minimized (block 250).

Circuit optimization problems may span across multiple designs or multiple design scenarios that require simulating different design netlists. Those different scenarios could include different process conditions (voltage, temperature, best/worst process condition), different circuit operating modes (e.g., Bitcell read vs. write), different circuit analyses (e.g., DC vs. transient analysis), different circuit types (e.g., a single MOSFET, various logical gates, ring oscillators), etc. Each of these design scenarios may require independent simulations using different netlists with potentially different input parameters and simulation output measurements.

Consider the example of a MOSFET, different benchmarking circuits including different types of ring oscillators, and independent simulations of the benchmarking circuits using different netlists with potentially different input model parameters and different simulation output measurements. The iterative adjustments may include adjusting work function model parameters to meet MOSFET threshold voltage (Vth) targets, and then mobility parameters to reach MOSFET effective current (Ieff) targets, and then capacitance model parameters to meet on-condition gate capacitance (Cgon) targets. Local layout effect parameters are also adjusted to meet ring oscillator frequency targets. Iterations continue until the cost function satisfies a termination criterion.

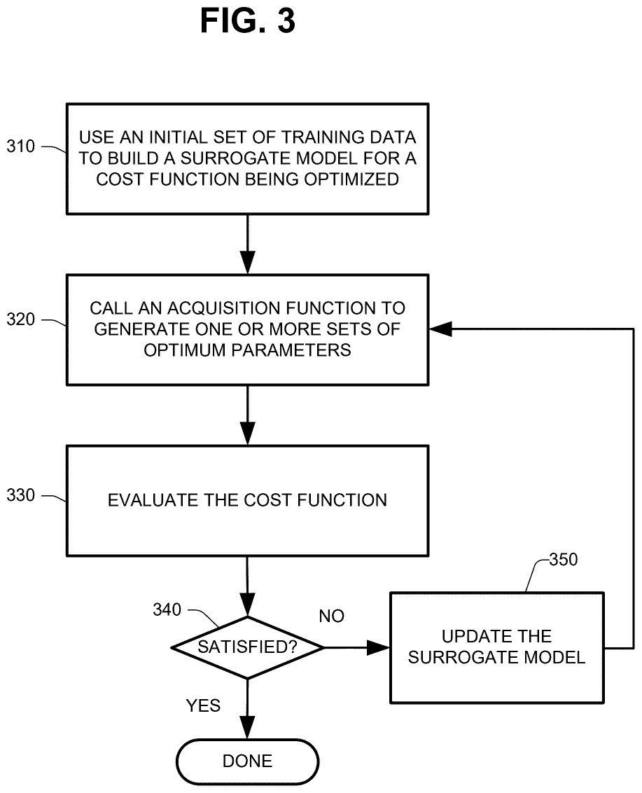

Reference is made to FIG. 3. Another approach for minimizing the cost function is Bayesian optimization. At block 310, an initial set of training data is used to build a surrogate model for a cost function being optimized. At block 320, an acquisition function is then called to generate one or more sets of optimization parameters (“candidates”) that both help improve the surrogate model as well as search for a global optimum. For example, a standard Gaussian Process Regression and an Upper Confidence Bound utility function in the acquisition function may be used to generate new candidates.

At block 330, the cost function is evaluated on the candidates. At block 340, if a termination criterion is not satisfied, then at block 350, the surrogate model is updated and the optimization loop repeats by returning control back to block 320. The surrogate model may be updated through posterior inferencing.

The combination of the variety of benchmarking circuits and the LLE evaluation greatly increases the accuracy of the recalibration. This, in turn, improves the ability to predict device behavior under different operating conditions (e.g., different voltage and current levels, temperature, and process variations). This, in turn, allows design engineers to further reduce the dependency on costly physical prototypes, saving additional time and resources.

### Detailed Example Method

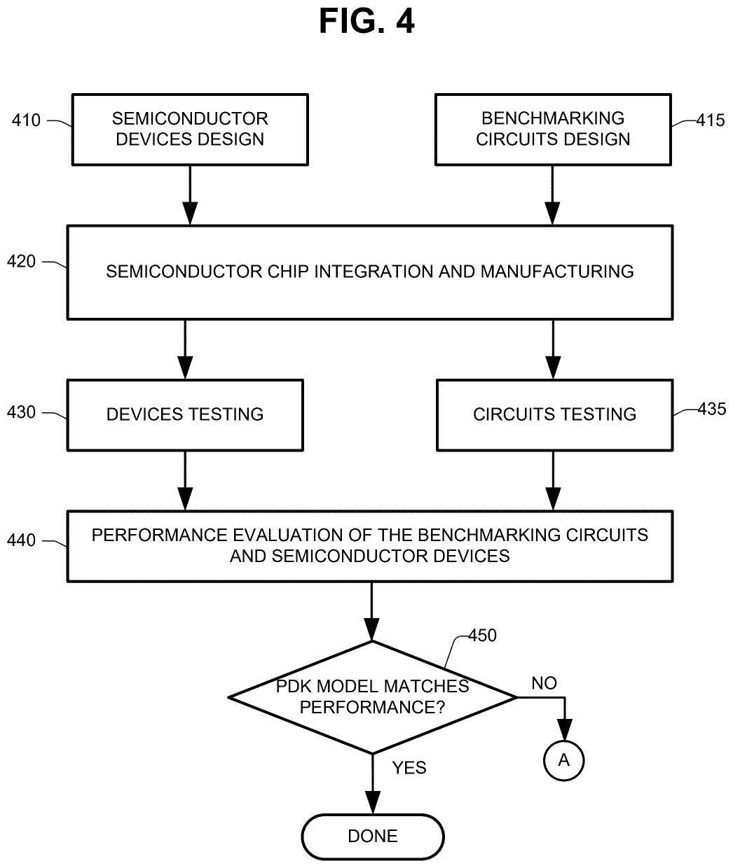

Reference is made to FIG. 4, which illustrates another example of a method for recalibration of MOSFET compact model parameters. At block 410, semiconductor device structures are designed. This may include generating a variety of layouts with different sizing and LLE environment.

At block 415, designs are created for benchmarking circuits that mimic different types of circuits in a product chip. A benchmarking circuit design may be automatically created from a register-transfer level (RTL) description and a library of available logic gates (a standard cell library), or the circuit may be designed manually with customization. A layout editor EDA tool may be used for customized design or automatic floor planning, placement, and wiring. A foundry may supply a process design kit (PDK), which provides a standard cell library, design rules, and compact models of semiconductor devices. Depending on device type, there are different Compact Model Coalition (CMC) industry standard models. As examples, BSIM-CMG is a standard compact model for MOSFETs and MEXTRAM is a standard compact model for bipolar junction transistors (BSIM is an acronym for Berkley, Short-channel IGFET Model, CMG is an acronym for Common Multi-Gate, and MEXTRAM is an acronym for Most Exquisite Transistor Model).

At block 420, the layouts of devices and benchmarking circuits are integrated into a chip, which is then manufactured by a foundry. In some instances, the product chip and benchmarking circuits are designed by a fabless semiconductor company, and the product chip will be manufactured by a foundry. In other instances, the design and manufacture will be performed by an integrated device manufacturer.

At blocks 430 and 435, both the devices and the circuits are tested. At block 430, silicon measurements of targets of semiconductor devices (e.g., MOSFETs) in the benchmarking circuits are taken. At block 435, silicon measurements of targets of the benchmarking circuits are taken.

At block 440, performance evaluation of the benchmarking circuits and semiconductor devices is performed. This involves identifying key performance metrics (“KPM”) of the circuit design and a semiconductor device. This may be done through simulation.

At block 450, a determination is made as to whether the compact model matches the KPMs of the devices and the benchmarking circuits. A match implies that the compact model simulation based on PEX netlist (which includes LLE effect) can perfectly predict multiple benchmark circuits and product performance.

However, a perfect match is very rare since product circuits and semiconductor devices such as MOSFETs often operate at different biases and temperature conditions. Additionally, MOSFETs and product circuits often demonstrate different local layout effect (LLE) which is originated from different layout environment. If there is no match, the compact model is recalibrated.

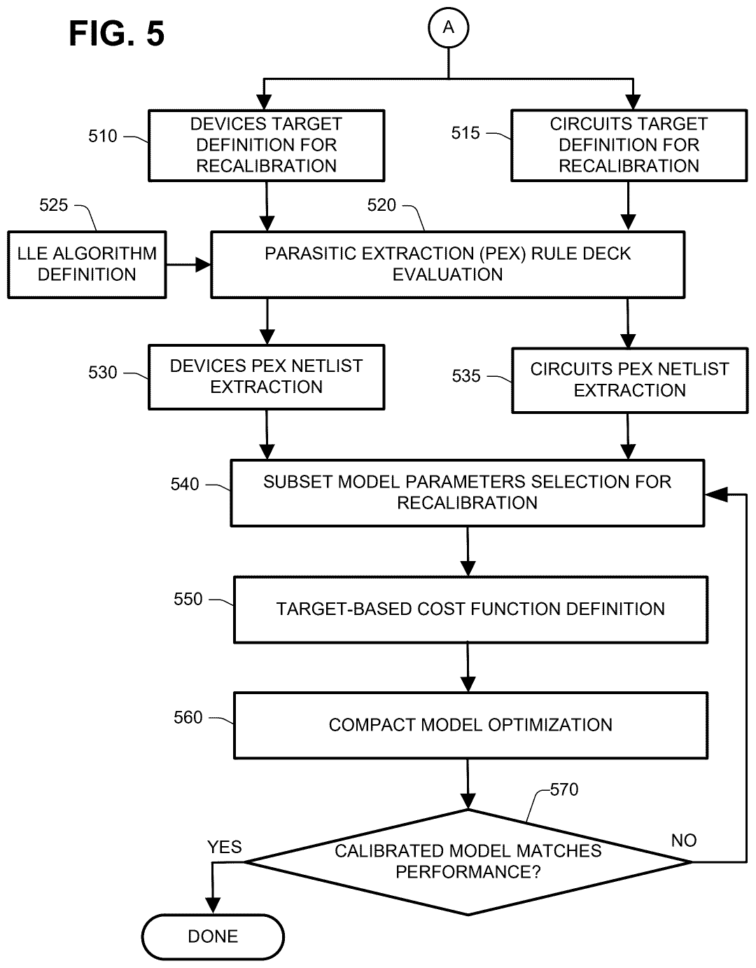

Reference is now made to FIG. 5. At block 510, KPM targets are defined for the semiconductor device. At block 515, KPM targets are defined for the circuit design.

At block 520, a parasitic extraction rule deck evaluation is performed to define PEX rules that accurately extract LLE relevant geometry values from a layout. At block 525, an LLE algorithm is defined by the foundry to describe LLE impact on device electrical behavior.

At block 530, a first complex PEX netlist including local layout effect (LLE) parameters for the device is extracted. At block 535, a second PEX netlist including LLE parameters for the benchmarking circuit is also extracted. At block 540, a subset of model parameters for recalibration is selected.

At blocks 550-570, optimization of the subset of parameters is performed. At block 550, a target-based cost function is defined. The cost function may be based on a weighted sum of individual cost functions for the device and benchmarking circuits.

At block 560, the benchmarking circuits are simulated with the PEX netlists and the compact model to predict KPM target values. If the cost function is not satisfied (block 570), the subset of parameters are adjusted to reduce the difference between measured and predicted target values, and control is returned to block 540, where a subset of model parameters is selected, followed by changing the model parameters, adjusting the cost function, and performing another simulation. Blocks 540-560 are repeated until the costs function is satisfied (block 570).

### Example Computing Environment

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

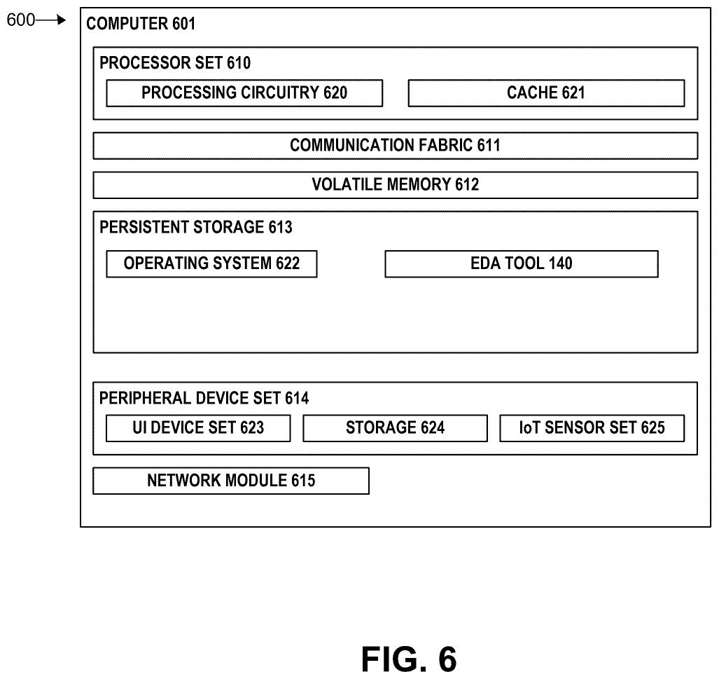

Reference is made to FIG. 6. A computing environment 600 includes an example of an environment for the execution of at least some of the computer code involved in performing the inventive methods. The computing environment 600 includes, for example, computer 601. The computing environment 600 may also include other features, such as a wide area network, end user device, remote server, public cloud, and private cloud (not shown). In this embodiment, the computer 601 includes processor set 610, communication fabric 611, volatile memory 612, persistent storage 613 (including operating system 622 and the EDA tool 140), peripheral device set 614 (including user interface (UI) device set 623, storage 624, Internet of Things (IoT) sensor set 625), and network module 615.

COMPUTER 601 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database. As is well understood in the art of computer technology, and depending upon the technology, performance of a computer-implemented method may be distributed among multiple computers and/or between multiple locations. On the other hand, in this presentation of computing environment 600, detailed discussion is focused on a single computer, specifically computer 601, to keep the presentation as simple as possible. Computer 601 may be located in a cloud, even though it is not shown in a cloud in FIG. 6. On the other hand, computer 601 is not required to be in a cloud except to any extent as may be affirmatively indicated.

PROCESSOR SET 610 includes one, or more, computer processors of any type now known or to be developed in the future. Processing circuitry 620 may be distributed over multiple packages, for example, multiple, coordinated integrated circuit chips. Processing circuitry 620 may implement multiple processor threads and/or multiple processor cores. Cache 621 is memory that is located in the processor chip package(s) and is typically used for data or code that should be available for rapid access by the threads or cores running on processor set 610. Cache memories are typically organized into multiple levels depending upon relative proximity to the processing circuitry. Alternatively, some, or all, of the cache for the processor set may be located “off chip.” In some computing environments, processor set 610 may be designed for working with qubits and performing quantum computing.

Computer readable program instructions are typically loaded onto computer 601 to cause a series of operational steps to be performed by processor set 610 of computer 601 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 621 and the other storage media discussed below. The program instructions, and associated data, are accessed by processor set 610 to control and direct performance of the inventive methods.

COMMUNICATION FABRIC 611 is the signal conduction path that allows the various components of computer 601 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 612 is any type of volatile memory now known or to be developed in the future. Examples include dynamic type random access memory (RAM) or static type RAM. Typically, volatile memory 612 is characterized by random access, but this is not required unless affirmatively indicated. In computer 601, the volatile memory 612 is located in a single package and is internal to computer 601, but, alternatively or additionally, the volatile memory may be distributed over multiple packages and/or located externally with respect to computer 601.

PERSISTENT STORAGE 613 is any form of non-volatile storage for computers that is now known or to be developed in the future. The non-volatility of this storage means that the stored data is maintained regardless of whether power is being supplied to computer 601 and/or directly to persistent storage 613. Persistent storage 613 may be a read only memory (ROM), but typically at least a portion of the persistent storage allows writing of data, deletion of data and re-writing of data. Some familiar forms of persistent storage include magnetic disks and solid state storage devices. Operating system 622 may take several forms, such as various known proprietary operating systems or open source Portable Operating System Interface-type operating systems that employ a kernel.

At least some of the instructions for performing the inventive methods may be stored in persistent storage 613 as part of the EDA tool 140.

PERIPHERAL DEVICE SET 614 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 624 is external storage, such as an external hard drive, or insertable storage, such as an SD card. Storage 624 may be persistent and/or volatile. In some embodiments, storage 624 may take the form of a quantum computing storage device for storing data in the form of qubits. In embodiments where computer 601 is required to have a large amount of storage (for example, where computer 601 locally stores and manages a large database) then this storage may be provided by peripheral storage devices designed for storing very large amounts of data, such as a storage area network (SAN) that is shared by multiple, geographically distributed computers. IoT sensor set 625 is made up of sensors that can be used in Internet of Things applications. For example, one sensor may be a thermometer and another sensor may be a motion detector.

NETWORK MODULE 615 is the collection of computer software, hardware, and firmware that allows computer 601 to communicate with other computers through a network. Network module 615 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 615 are performed on the same physical hardware device. In other embodiments (for example, embodiments that utilize software-defined networking (SDN)), the control functions and the forwarding functions of network module 615 are performed on physically separate devices, such that the control functions manage several different network hardware devices. Computer readable program instructions for performing the inventive methods can typically be downloaded to computer 601 from an external computer or external storage device through a network adapter card or network interface included in network module 615.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A method comprising:
testing a plurality of benchmarking circuits that mimic different types of circuits in a product chip to produce measurements of targets of a semiconductor device in the benchmarking circuits and measurements of targets of the benchmarking circuits;
performing computer simulations of the plurality of benchmarking circuits with local layout effect (LLE) evaluation to predict values of the targets of the semiconductor device and the targets of the benchmarking circuits; and
using the measurements and predicted values of the targets to perform recalibration of a compact model of the semiconductor device.

2. The method of claim 1, wherein the benchmarking circuits mimic the product chip in at least one of figures of metrics (FOM), layouts, and different topologies in the product chip.

3. The method of claim 1, wherein:
each benchmarking circuit comprises a multi-stage ring oscillator for representing main logic gates; and
the targets of the benchmarking circuits include power and leakage.

4. The method of claim 1, wherein the compact model is a compact model of a MOSFET.

5. The method of claim 1, further comprising:
extracting parasitic extraction (PEX) netlists for the semiconductor device;
extracting PEX netlists for the benchmarking circuits; and
using the PEX netlists in the computer simulations.

6. The method of claim 5, wherein the netlists include parameters for capacitors, resistors and local layout effect.

7. The method of claim 1, wherein using the measurements and predicted values of the targets to perform the recalibration comprises:
selecting a subset of parameters for the recalibration; and
iteratively adjusting the subset of parameters to minimize a cost function that is based on a difference between the measurements and predicted values of the targets.

8. The method of claim 7, wherein the subset of parameters are iteratively adjusted via Bayesian optimization.

9. The method of claim 1, wherein performing the computer simulations and using the measurements and the predicted values to recalibrate the compact model are computer-implemented.

10. The method of claim 1, further comprising fabricating the plurality of benchmarking circuits.

11. A computer-implemented method, comprising:
accessing measurements taken from a plurality of benchmarking circuits, the measurements including measurements of targets of semiconductor devices in the benchmarking circuits and measurements of targets of the benchmarking circuits;
accessing a semiconductor device compact model;
performing simulations of the plurality of benchmarking circuits with local layout effect (LLE) evaluation to predict values of the targets of the semiconductor devices and the targets of the benchmarking circuits; and
adjusting a subset of parameters of the compact model to reduce error between the measurements and predicted values of the targets.

12. The method of claim 11, further comprising iteratively performing the simulations with adjusted parameters of the compact model and then adjusting the parameters again until a cost function is satisfied.

13. The method of claim 12, wherein the adjusted parameters are computed via Bayesian optimization.

14. The method of claim 11, wherein the compact model is a compact model of a MOSFET.

15. The method of claim 11, further comprising:
extracting parasitic extraction (PEX) netlists for the semiconductor devices;
extracting PEX netlists for the benchmarking circuits; and
using the PEX netlists in the simulations.

16. The method of claim 15, wherein the netlists include parameters for capacitors, resistors and local layout effect.

17. A computer comprising:
memory having computer readable instructions; and
a processor set for executing the computer readable instructions to configure the computer to perform a method comprising:
receiving measurements of targets of a plurality of benchmarking circuits including semiconductor devices;
receiving measurements of targets of the semiconductor devices;
performing simulations of the plurality of benchmarking circuits with local layout effect (LLE) evaluation to predict values of the targets of the semiconductor device and the targets of the benchmarking circuits; and
using the measurements and predicted values of the targets to perform recalibration of a semiconductor device compact model.

18. The computer of claim 17, further comprising:
extracting parasitic extraction (PEX) netlists for the semiconductor devices;
extracting PEX netlists for the benchmarking circuits; and
using the PEX netlists in the simulations.

19. The computer of claim 18, wherein the PEX netlists include parameters for capacitors, resistors and local layout effect.

20. The computer of claim 17, wherein using the measurements and the predicted values of the targets to perform the recalibration comprises:
performing Bayesian optimization to find a subset of parameters that minimize a cost function.

21. A computer program product comprising one or more computer-readable memory devices encoded with data including instructions that, when executed, causes a processor set to perform a method comprising:
receiving measurements of targets of a plurality of benchmarking circuits including a semiconductor device;
receiving measurements of targets of the semiconductor device;
performing simulations of the plurality of benchmarking circuits with local layout effect (LLE) evaluation to predict values of the targets of the semiconductor device and the targets of the benchmarking circuits; and
using the measurements and predicted values of the targets to perform recalibration of a compact model of the semiconductor device.

22. The computer program product of claim 21, further comprising:
extracting parasitic extraction (PEX) netlists for the semiconductor device;
extracting PEX netlists for the benchmarking circuits; and
using the PEX netlists in the simulations.

23. The computer program product of claim 22, wherein the PEX netlists include parameters for capacitors, resistors and local layout effect.

24. The computer program product of claim 21, wherein using the measurements and the predicted values of the targets to perform the recalibration comprises:
performing Bayesian optimization to find a subset of parameters that minimize a cost function.

25. A method for recalibration of parameters of a metal oxide semiconductor field effect transistor (MOSFET) compact model, the method comprising:
evaluating a MOSFET design and a circuit design for benchmarking;
testing the circuit design to produce measurements of targets of MOSFETs in the circuit design and measurements of targets of the circuit design;
identifying key performance metrics (“KPM”) of the circuit design and the MOSFET design;
determining whether the compact model and the circuit design match the KPMs of the MOSFETs and the circuit design;
if there is no match, defining recalibration KPM targets for the MOSFET design and recalibration KPM targets for the circuit design;
extracting a first complex parasitic extraction (PEX) netlist including local layout effect (LLE) parameters for the MOSFET design;
extracting a second PEX netlist including LLE parameters for the circuit design;
selecting a subset of model parameters for recalibration; and
performing optimization of the subset of parameters, comprising:
simulating the circuit design with the PEX netlists and the compact model to predict KPM target values; and
adjusting the subset of parameters to minimize a cost function based on the measurements and the KPM target values.
